(19) United States
(12) Patent Application Publication
(10) Pub. No.: US 2012/0119305 A1
(43) Pub. Date: May 17, 2012

(54) LAYOUT OF POWER MOSFET

(75) Inventors: KUO-CHIANG CHEN, TAIPEI COUNTY 251 (TW); YEN-YI CHEN, TAIPEI COUNTY 241 (TW); CHIEN PING CHOU, KAOHSIUNG CITY 807 (TW)

(73) Assignee: FORTUNE SEMICONDUCTOR CORPORATION, TAIPEI HSIEN (TW)

(21) Appl. No.: 12/948,068

(22) Filed: Nov. 17, 2010

(51) Int. Cl. H01L 29/78

(52) U.S. Cl. 257/401; 257/E29.255

(57) ABSTRACT

A layout of a power MOSFET includes a first zigzag gate structure located on a substrate of the power MOSFET and having a first side and a second side, a first contact located on the substrate and at the first side of the first zigzag gate structure, and a second contact structure located on the substrate and at the second side of the first zigzag gate structure.

### BACKGROUND OF THE INVENTION

1. Field of the Invention

The present invention relates to a layout of a power metal-oxide- semiconductor field-effect transistor (MOSFET), and more particularly, to a layout of a gate structure with an increased channel width for a power MOSFET of the same size.

2. Description of Related Art

A voltage converter utilized in a direct current (DC)-DC converter, a low dropout regulator (LDO), a switching regulator and a charger requires the power MOSFET thereof in a larger size when a dropout voltage, a resistance between a drain and a source (Rdson), and an output current are all taken into account.

FIG. 1A is a schematic view of a layout of a conventional power MOSFET. A power MOSFET 1 has a strip-shaped gate structure 14 on a substrate 100. At both sides of the substrate 100 lies one or more contacts 10 and 12 where a drain structure and a source structure of the power MOSFET 1 are located. As shown in FIG. 1A, the channel width of the power MOSFET 1 is represented as W, and the channel length thereof is L.

FIG. 1B is a schematic view of a layout of another conventional power MOSFET. Referring to FIG. 1A and FIG. 1B, a power MOSFET 1′ may be in a larger size when compared with the power MOSFET 1 with more than one strip-shaped gate structure. For example, two strip-shaped gate structure 14 and 16. Additional contacts 18 may be placed on a substrate 102 of the power MOSFET 1′ in addition to the contacts 10 and 12 shown in the power MOSFET 1. The contacts 10 and 18 respectively may be used as a drain structure and a source structure of the power MOSFET 1′. Meanwhile, the contact 12 may be used as a common node. As such, the power MOSFET 1′ may be regarded as two power MOSFETs 1 connected in series.

Despite the power MOSFET 1′, which is larger in size, may be capable of outputting more current, a larger layout area associated with the power MOSFET 1′ is thus required at the expense of the density thereof with increased manufacturing cost.

### SUMMARY OF THE INVENTION

The object of the present invention discloses a layout of a power MOSFET which is capable of outputting a larger output current in the same size as a conventional power MOSFET, while having smaller dropout voltage and resistance between a drain and a source.

According to one embodiment, the layout of the power MOSFET of the invention includes a first zigzag gate structure on a substrate with a first side and a second side, a first contact on the substrate and located on the first side of the first zigzag gate structure, and a second contact on the substrate and located at the second side of the first zigzag gate structure.

The zigzag gate structure is used for increasing an effective channel width of the power MOSFET so as to achieve the goal of increasing the output current while decreasing the dropout voltage and the resistance between the drain and the source.

In order to further the understanding regarding the present invention, the following embodiments are provided along with illustrations to facilitate the disclosure of the present invention.

### BRIEF DESCRIPTION OF THE DRAWINGS

FIG. 1A is a schematic view of a conventional MOSFET;

FIG. 1B is a schematic view of another conventional MOSFET;

FIG. 2A is a schematic view of a layout of a first embodiment of the present invention;

FIG. 2B is a schematic view of a layout of a second embodiment of the present invention;

FIG. 3A is a schematic view of a layout of a third embodiment of the present invention;

FIG. 3B is a schematic view of a layout of a fourth embodiment of the present invention; and

FIG. 4 is a schematic view of a layout of a fifth embodiment of the present invention.

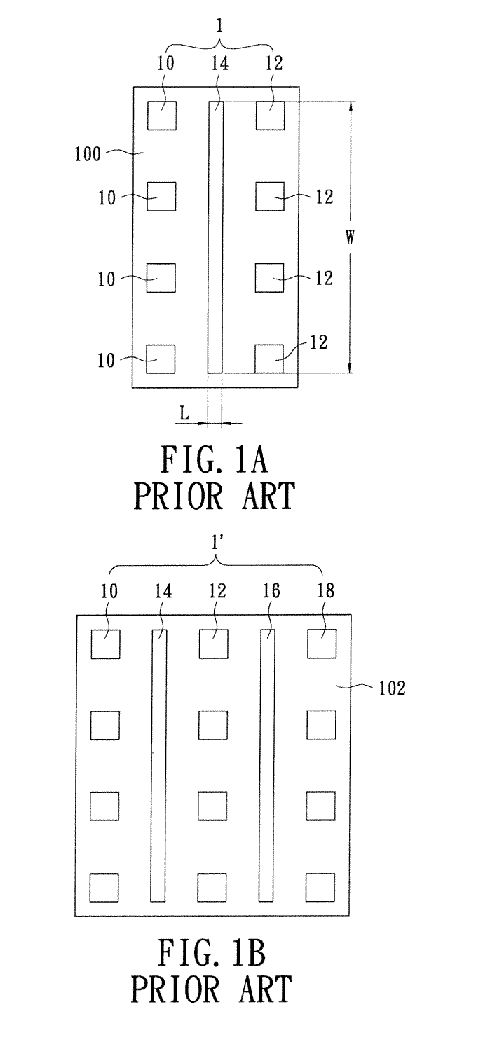

### DETAILED DESCRIPTION OF THE PREFERRED EMBODIMENTS

The aforementioned illustrations and following detailed descriptions are exemplary for the purpose of further explaining the scope of the present invention. Other objectives and advantages related to the present invention will be illustrated in the subsequent descriptions and appended tables.

In order to effectively solve the problem of increasing manufacturing cost associated with the conventional large power MOSFET, this invention is disclosed to provide a gate structure of zigzag shape (such as Z-shaped, S-shaped, or square wave-shaped) on a substrate of a power MOSFET according to the present invention. The gate structure of the zigzag shape allows for the increased effective channel width with the same size as that of the conventional power MOSFET.

According to following equation (1), an output current I_{D} is proportional to the effective channel width. Therefore, so long as the effective channel width may increase the output current may increase. Furthermore, the power MOSFET with increased output current capacity normally is generally associated with the smaller dropout voltage and the smaller resistance between the drain and the source of the power MOSFET.

I_{D}=½ β₀W/L(V_{GS}−Vₜₕ)² (1)

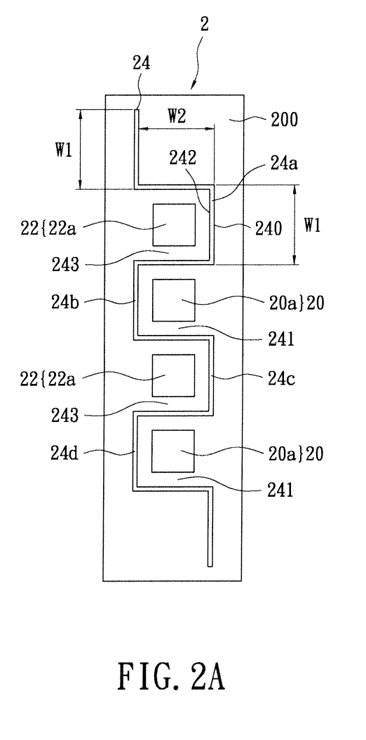

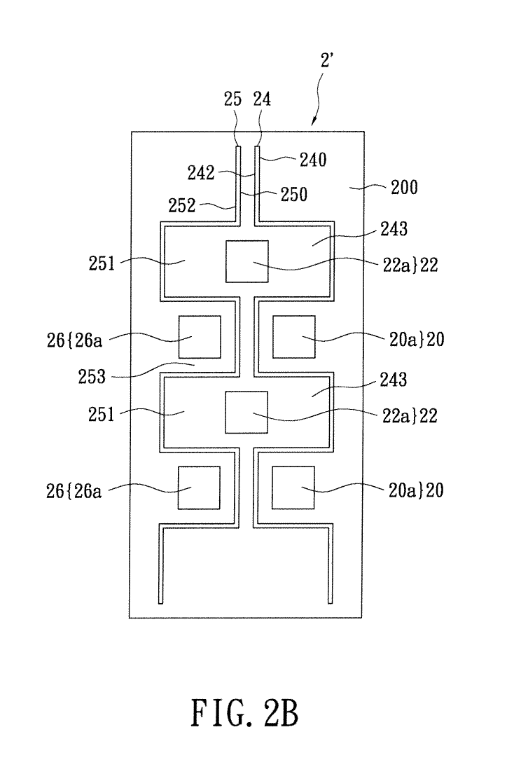

FIG. 2A is a schematic view of a layout of a first embodiment of the invention. A layout of the power MOSFET according to the invention includes a first contact 20, a second contact 22, and a first zigzag gate structure 24. The first zigzag gate structure 24 is located on a substrate 200, and has a first side 240 and a second side 242. The first contact 20 is located on the substrate 200 and at the first side 240 of the first zigzag gate structure 24. The second contact 22 is located on the substrate 200 and at the second side 242 of the first zigzag gate structure 24.

Referring to FIG. 2A, the first zigzag gate structure 24 in the layout 2 of the power MOSFET consists of a plurality of bent sections 24a, 24b, 24c, and 24d. The bent sections 24a, 24b, 24c, and 24d may be in a series connection. More specifically, neighboring bent sections may face in opposite directions. As the summation of lengths of the bent sections 24a, 24b, 24c, and 24d may be the channel width of the first zigzag gate structure 24, the channel width of the power MOSFET according to the present invention may be larger than that of the conventional strip-shaped MOSFET in the same size.

Since the layout 2 of MOSFET of the invention corresponds to the larger effective channel width compared to the conventional power MOSFET, the output current capability may thus enhance. With the enhanced output current capability, the MOSFET of the present invention may be associated with the smaller dropout voltage and smaller resistance between the drain and the source.

Referring to 2A, one or more recessions 241 may be formed on the first side 240 of the first zigzag gate structure 24. For example, the bent section 24a of the first zigzag gate structure 24 may be associated with the first side 240. The first contact 20 has one or more contact parts such as 20a which may be located in the recessions 241, which are formed with the bent sections 24a and 24c serving as bottoms of the corresponding recessions 241. Furthermore, one or more recessions 243 may be formed on the second side 242 of the first zigzag gate structure 24. The second contact 22 has one or more contact parts 22a which are located in the recessions 243. It is worth noting that the locations of the contact parts 20a and 22a may be located in the recessions 243 on the second side 242 and the recessions 241 on the first side 240, respectively, also. The contact parts 20a and 22a may be either drain contact parts or source contact parts so that they may serve as drains or sources of the power MOSFET.

FIG. 2B is a schematic view of a layout of a second embodiment of the invention. A layout 2′ of the power MOSFET includes, in addition to the first contact 20, the second contact 22 and the first zigzag gate structure 24 shown in the first embodiment, a second zigzag gate structure 25 and a third contact 26.

As shown in FIG. 2B, the first zigzag gate structure 24 is disposed adjacent to the second zigzag gate structure 25. The first zigzag gate structure 24 and the second zigzag gate structure 25 may face in opposite directions. In one implementation, the first zigzag gate structure 24 and the second zigzag structure 25 may face to each other. The second zigzag gate structure 25 may be associated with a third side 250 and a fourth side 252. One or more recessions 251 may be formed on the third side 250 while one or more recessions 253 may be formed on the fourth side 252. The second contact 22 may be located on the recession 251 of the third side 250 of the second zigzag gate structure 24. Furthermore, the third contact 26 may be located on the substrate 200 and at the fourth side 252 of the second zigzag gate structure 25. The third contact 26 has one or more contact parts 26a located in the recessions 253 of the fourth side 252 of the second zigzag gate structure 25. The first contact parts 20a may be located in the recessions formed on the first side 240 of the first zigzag gate structure 24 while the second contact parts 22a may be located between the recessions 243 and 251.

The contact parts 20a and 26a are either source contact parts or drain contact parts. More specifically, when the contact parts 20a are source parts the contact parts 26a may be drain parts. Therefore, the contact parts 20a may serve as the source of the power MOSFET 2′ with the contact parts 26a serving as the drain thereof. Meanwhile, the contact parts 22a may be used as the common node. The power MOSFET 2′ may be a combination of two power MOSFETs 2 connected in series.

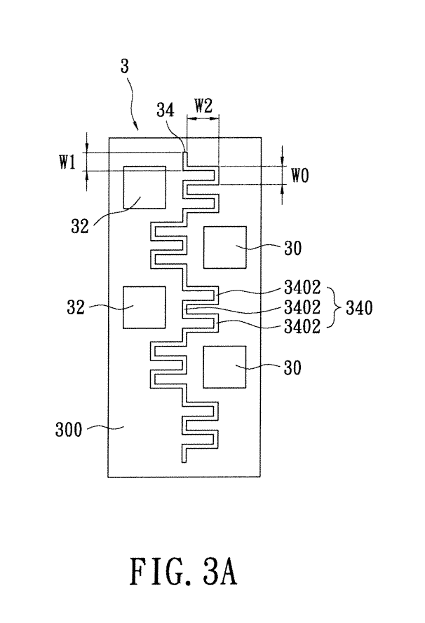

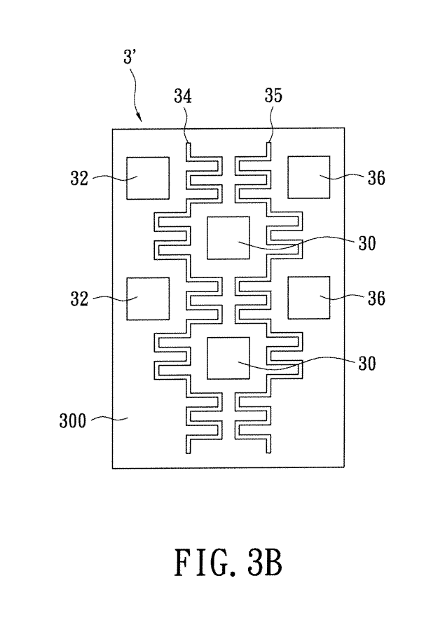

FIG. 3A is a schematic view of a layout of third embodiment of the invention. In order to increase the effective channel width of the power MOSFET, in a layout 3 of the power MOSFET of the present invention a third zigzag gate structure 34 consisting of a plurality of bent sections 340 connected in series is provided. Each bent section 340 consists of a plurality of bent units 3402 connected in series. As shown in FIG. 3A, the effective channel width W is the summation of lengths of the bent units such as W0, W1, and W2. Thereby, the effective channel width W of the layout 3 of the power MOSFET of the third embodiment may further increase compared with that of the layout 2.

FIG. 3B is a schematic view of a layout of a fourth embodiment of the invention. Compared with the embodiment in FIG. 3A (layout 3 of the power MOSFET), a layout 3′ of the MOSFET illustrated in FIG. 3B further includes another zigzag gate structure 35.

As shown in FIG. 3B, the zigzag gate structure 34 and the zigzag gate structure are located on the substrate 300 and face in opposite directions. Contacts 32 and 36 may be located on two sides of a substrate 300 of the MOSFET 3′. More specifically, the contacts 32 and 36 may be located on one side of each of the zigzag gate structure 34 and the zigzag gate structure 35, respectively. Contacts 30, on the other hand, may be located between the zigzag gate structure 34 and the zigzag gate structure 35. In one implementation, the contacts 32 and 36 respectively serve as the drain and the source of the power MOSFET 3′.

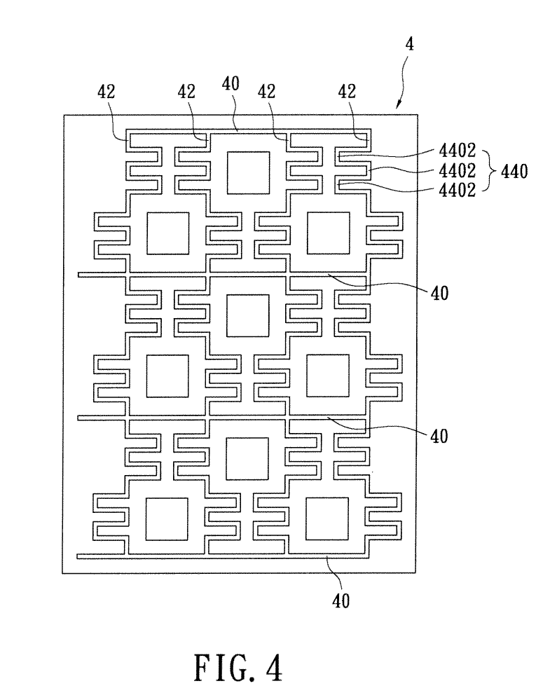

FIG. 4 is a schematic view of a fifth embodiment of the invention. A layout 4 of the power MOSFET includes a plurality of zigzag gate structures 42 and one or more coupling structures 40. Coupling structures 40 are adapted to connect the zigzag gate structures 40 and 42. As shown in FIG. 4, the zigzag gate structure 42 consists of one or more bent sections 440 connected in series and in a zigzag manner. Each of the bent sections 440 consists of a plurality of bent units 4402.

In the light of above, as with the same size of the conventional power MOSFET the zigzag-shaped gate structures of the power MOSFET in various embodiments of the invention increase the effective channel width as the result of the extended lengths of the gate structures. As such, the power MOSFET may be capable of outputting larger output currents while decreasing the dropout voltage and the resistance between the drain and the source

The descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

What is claimed is:

1. A layout of a power MOSFET comprising:
a first zigzag gate structure, located on a substrate of the power MOSFET, having a first side and a second side:
a first contact structure, located on the substrate and at the first side of the first zigzag gate structure; and
a second contact structure located on the substrate of the power MOSFET.

2. The layout of the power MOSFET of claim 1, wherein a channel width of the first zigzag gate structure is a length of the first zigzag structure.

3. The layout of the power MOSFET of claim 2, wherein the first side of the first zigzag gate structure forms one or more recessions.

4. The layout of the power MOSFET of claim 3, wherein the first contact has one or more contact parts located at the recessions.

5. The layout of the power MOSFET of claim 4, wherein the contact part associated with the first contact is a source contact part or a drain contact part.

6. The layout of the power MOSFET of claim 2, wherein the second side of the first zigzag gate structure forms one or more recessions.

7. The layout of the power MOSFET of claim 6, wherein the second contact has one or more contact parts located at the recessions formed at the second side of the first zigzag gate structure.

8. The layout of the power MOSFET of claim 7, wherein the contact part associated with the second contact is a source contact part or a drain contact part.

9. The layout of the power MOSFET of claim 2, wherein the first zigzag gate structure consists of a plurality of bent sections in a series connection and the neighboring bent sections are disposed facing in opposite directions.

10. The layout of the power MOSFET of claim 9, wherein the bent section has one or more bent unit.

11. The layout of the power MOSFET of claim 2, further comprising:
a second zigzag gate structure on the substrate and disposed adjacent to the first zigzag gate structure and facing in an opposite direction with respect to the first zigzag gate structure, wherein the second zigzag gate structure has a third side and a fourth side, and the second contact is located between the third side of the second zigzag gate structure and the second side of the first zigzag gate structure; and
a third contact located on the substrate and at the fourth side of the second zigzag gate structure.

12. The layout of the power MOSFET of claim 11, further comprising one or more coupling structures each of which is connected to the neighboring first zigzag structure and the second gate structure.
